(19) United States
(12) Patent Application Publication
(10) Pub. No.: US 2008/0075159 A1
(43) Pub. Date: Mar. 27, 2008

(54) Receiver having multiple stages of equalization with tap coefficient copying

(76) Inventors: Uwe Sontowski, Riverview (AU); Graeme K. Woodward, Epping (AU)

Correspondence Address: MENDELSOHN & ASSOCIATES, P.C., 1500 JOHN F. KENNEDY BLVD., SUITE 405, PHILADELPHIA, PA, 19102, US

(21) Appl. No.: 11/731,173

(22) Filed: Mar. 30, 2007

Related U.S. Application Data
(60) Provisional application No. 60/826,391, filed on Sep. 21, 2006.

(51) Int. Cl. H03H 7/40; H03K 5/159

(52) U.S. Cl. 375/232

(57) ABSTRACT

In one embodiment, a receiver has a main equalizer and an auxiliary equalizer. The auxiliary equalizer equalizes a received signal using adaptively generated sets of auxiliary filter coefficients. Each set is generated by 1) filtering a received signal to generate an equalized signal, 2) calculating an error based on the equalized signal, and 3) calculating the set of coefficients based on the error and the prior set of auxiliary filter coefficients. The main equalizer equalizes a delayed version of the input signal by first applying a set of auxiliary filter coefficients, copied from the auxiliary equalizer, to the delayed version. Then, the main equalizer continues to equalize the delayed signal using main filter coefficients that are adaptively generated in a manner analogous to that of the auxiliary equalizer. In other embodiments, the number of sets of auxiliary filter coefficients and the period in which the sets are copied may vary.

### CROSS-REFERENCE TO RELATED APPLICATIONS

The subject matter of this application is related to PCT patent application no. PCT/US07/00622 filed 10 Jan. 2007 as attorney docket no. Banna 3-2-2-3, and U.S. patent application Ser. No. 11/710,212 filed 23 Feb. 2007 as attorney docket no. Cooke 2-7-4 the teachings of which are incorporated herein by reference.

### BACKGROUND OF THE INVENTION

1. Field of the Invention

The present invention relates to signal processing receivers, and, more specifically, to equalizing signals received by such devices.

2. Description of the Related Art

FIG. 1 shows a simplified block diagram of one implementation of a prior-art receiver 100 which employs a single stage of equalization. Receiver 100 has upstream processing 102 which performs pre-equalization processing that might include processing such as analog-to-digital conversion, root raised-cosine filtering, or other processing to prepare a received signal for equalization. Normalized-least-mean-squares (NLMS) equalizer 104 receives digital data y(i) from upstream processing 102, equalizes signal y(i) to closely approximate the original pre-transmission signal, and outputs equalized signal \hat{x}(i) to downstream processing 106. Downstream processing 106 then performs post-equalization processing, which might include de-scrambling, de-spreading, symbol estimation, data symbol de-mapping, or other post-equalization processing for recovering one or more output data streams from the received signal.

NLMS equalizer 104 equalizes digital signal y(i) using an update loop which comprises finite impulse response (FIR) filter 108, coefficient updater 110, and error calculator 112. FIR filter 108 receives incoming digital signal y(i), applies sets of updated coefficients w(i+1) to signal y(i), and outputs equalized signal \hat{x}(i) according to Equation (1) as follows:

\hat{x}(i)=w*(i+1)y(i) (1)

where w*(i+1) is the complex conjugate transpose of the updated coefficient vector w(i+1). Each set of updated coefficients w(i+1) is calculated by coefficient updater 110 using (1) received signal y(i), (2) the previous set of coefficients w(i), and (3) an error signal e(i) received from error calculator 112. Error signal e(i) is calculated with the aid of a reference signal z(i). Further, error signal e(i) and the set of coefficients w(i+1) are continuously updated at a maximum rate of one update per chip interval.

Coefficient Calculation Using a Normalized-Least-Mean-Squares Approach

Coefficients w(i+1) may be calculated using any one of a number of approaches commonly known in the art. According to the embodiment of FIG. 1, coefficient updater 110 receives signal y(i) and error signal e(i) and calculates new coefficients w(i+1) using a normalized-least-mean-squares (NLMS) approach. The NLMS approach is a variation of the least-mean-squares (LMS) approach, wherein each new coefficient w(i+1) is calculated as shown in Equation (2) below:

w_{LMS}(i+1)=w_{LMS}(i)−μ∇_{w}E[|e(i)|²], (2)

where ∇_{w} is the gradient of the expectation value E[|e(i)|²] of the square of error signal e(i), and μ is the update step size.

The expected value E[|e(i)|²] (a.k.a., mean squared error (MSE)) can be represented as an “error performance surface.” A gradient descent approach is used to step across the surface to arrive at the minimum-mean-squared error (MMSE), which is represented by a local minimum on the surface. As the MSE of Equation (2) approaches the MMSE, the accuracy of tap weights w(i+1) increases. Substituting an instantaneous estimate for the expectation of Equation (2) yields the particular LMS calculation of Equation (3) as follows:

w_{LMS}(i+1)=w_{LMS}(i)−Δy(i)e* (i), (3)

where a small scalar is chosen as the step size Δ and e*(i) is the complex conjugate of error signal e(i). To obtain the NLMS coefficients w_{NLMS}(i+1), LMS Equation (3) is normalized to produce Equation (4) as follows:

$${w}_{NLMS} ( i + 1 ) = {w}_{NLMS} ( i ) - \tilde{Δ} \frac{y ( i ) {e}^{*} ( i )}{{‖ y ( i ) ‖}^{2}} . \qquad ( 4 )$$

### As shown, new NLMS coefficients w_{NLMS}(i+1) use a normalized step size \tilde{Δ}.

Error Calculation

The accuracy of NLMS equalizer 104 in approximating the original pre-transmission signal is measured by error signal e(i). Thus, a smaller error e(i) represents improved equalizer performance. Error signal e(i) is obtained by comparing equalized output \hat{x}(i) of FIR filter 108 to a reference signal x(i) as shown in Equation (5) below:

e(i)=\hat{x}(i)−x(i) (5)

Reference signal x(i) represents an expected value for the received signal, neglecting the effects of transmission. Thus, error signal e(i) decreases as equalized output \hat{x}(i) more closely approximates expected reference x(i) known by receiver 100.

In typical transmissions, a large portion of the transmitted signal is not known by the receiver. However, a pilot signal z(i), which contains a known sequence of bits, may be transmitted for training and tracking purposes. Substituting pilot z(i) for reference x(i) in Equation (5) yields error signal e′(i) as shown in Equation (6):

e′(i)=\hat{x}(i)−z(i) (6)

### The complex conjugate of error signal e′(i) may then be substituted for error e*(i) in Equation (4) to produce new NLMS coefficients w_{NLMS}(i+1).

Training of the Receiver

During startup of the receiver and after periods of discontinuity in data transmissions, the receiver adjusts (i.e., trains) to new channel conditions. During this training period, receiver 100 attempts to rapidly converge on the MMSE. Failure to rapidly converge may lead to an error in recovering the one or more output data streams, and consequently, the data may need to be retransmitted.

Several methods commonly known in the art have been employed to reduce the number of retransmissions resulting from slow convergence. In a first such method, equalizer parameters such as step size \tilde{Δ} may be tuned for optimum convergence. For example, step size \tilde{Δ} may be made larger for more rapid initial convergence. However, as step size \tilde{Δ} is increased, adaptation noise in the coefficient calculations reduces the accuracy of coefficients w(i+1), which in turn can lead to errors in downstream processing 106. As step size \tilde{Δ} is decreased, the adaptation noise is decreased and the final convergence on the MMSE may be more accurate. However, as step size \tilde{Δ} decreases, the time for convergence increases. A gear-shifting method may be employed in which NLMS equalizer 104 increases step size \tilde{Δ} to force more aggressive convergence initially, and then decreases step size \tilde{Δ} to fine-tune the MMSE. While gear-shifting methods are effective, they may still be insufficient and lead to errors in recovering the one or more output data streams.

In another such method, discontinuities in transmissions could be prevented. Thus, once the receiver has trained to the channel, the channel may be continuously tracked by the receiver. Continuous tracking by the receiver is very power intensive and can lead to reduced battery life of the user equipment (UE). Furthermore, continuous tracking does not address circumstances in which fast equalizer startup is required, such as after a severe channel change.

In yet another such method, the receiver can use a block-based approach which accumulates data over a block of time. The properties of the channel are then measured based on the stored data and convergence on the MMSE can be obtained using the measured channel properties. This approach is computationally complex and prone to numerical instability. Also, since the data is accumulated over a period of time, latency of the receiver is increased.

### SUMMARY OF THE INVENTION

In one embodiment, the present invention is a method for equalizing a received signal. The method has a first stage of equalization and a second stage of equalization. The first stage of equalization is performed to generate a set of auxiliary filter coefficients based on the received signal. The second stage of equalization is performed to generate a set of main filter coefficients based on a delayed version of the received signal and the set of auxiliary filter coefficients.

In another embodiment, the present invention is a receiver having one or more equalizers for performing the first and second stages of equalization described in the previous paragraph.

### BRIEF DESCRIPTION OF THE DRAWINGS

Other aspects, features, and advantages of the present invention will become more fully apparent from the following detailed description, the appended claims, and the accompanying drawings in which like reference numerals identify similar or identical elements.

FIG. 1 shows a simplified block diagram of one implementation of a prior-art receiver which employs a single stage of equalization;

FIG. 2 shows a simplified block diagram of a receiver having two stages of equalization with coefficient copying according to one embodiment of the present invention;

FIG. 3 graphically illustrates representations of mean-squared error profiles for the receivers of FIG. 1 and FIG. 2;

FIG. 4 shows a simplified block diagram of a receiver having multiple pipelined stages of equalization with coefficient copying according to one embodiment of the present invention; and

FIG. 5 shows a simplified block diagram of a receiver according to one embodiment of the present invention that has two stages of equalization which are implemented iteratively.

### DETAILED DESCRIPTION

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

Overview of Receiver According to One Embodiment of the Present Invention

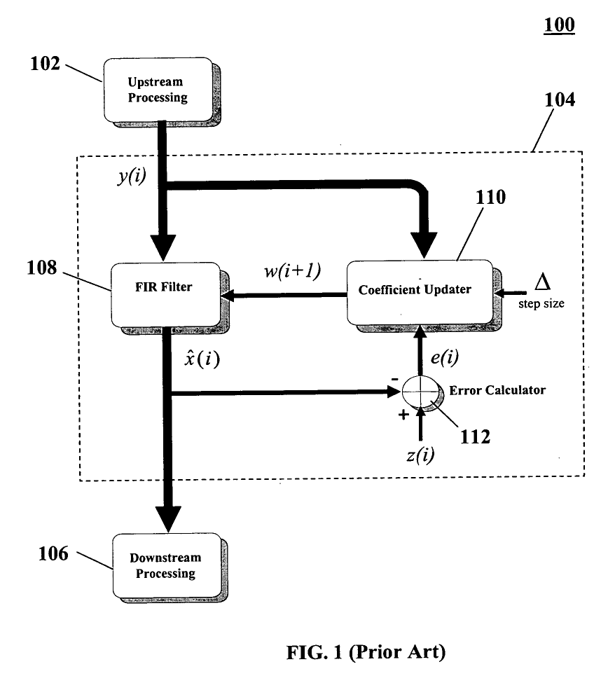

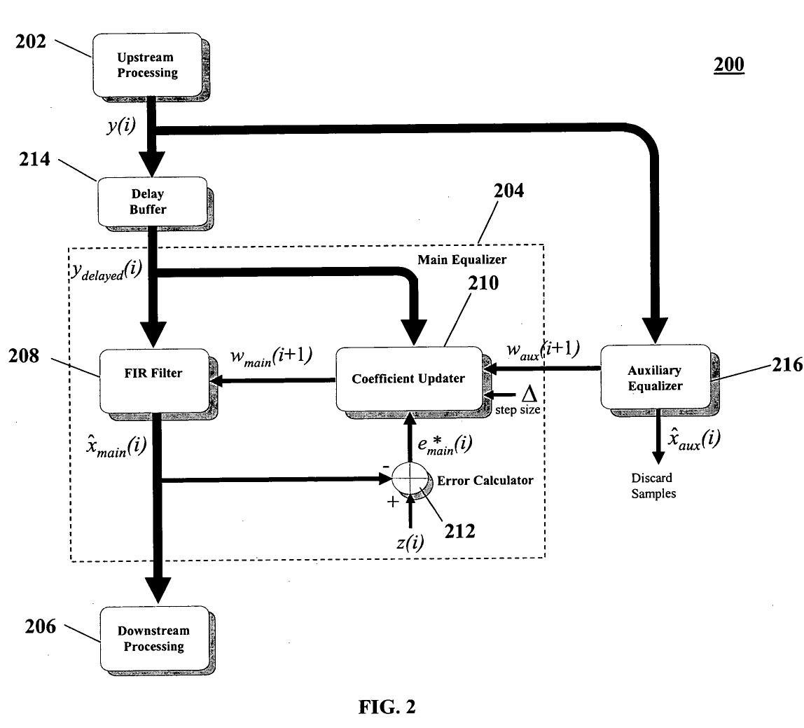

FIG. 2 shows a simplified block diagram of a receiver 200 having two stages of equalization with coefficient copying according to one embodiment of the present invention. Receiver 200 has upstream processing 202 which performs operations analogous to that of upstream processing 102 of prior-art receiver 100 of FIG. 1 to generate received digital signal y(i). Received digital signal y(i) is then provided to auxiliary NLMS equalizer 216 and delay buffer 214.

Auxiliary NLMS equalizer 216 performs a first pass (i.e., the first stage) over the samples of received signal y(i) by equalizing received signal y(i) in a manner similar to that of equalizer 104 of prior-art receiver 100. In so doing, auxiliary NLMS equalizer 216 generates sets of auxiliary filter coefficients wₐᵤₓ(i+1) (e.g., as shown in Equation (4)), and applies the sets of coefficients wₐᵤₓ(i+1) to received signal y(i) to generate equalized output \hat{x}ₐᵤₓ(i), which is subsequently discarded. Additionally, during the first pass, auxiliary NLMS equalizer 216 provides (i.e., copies) one or more sets of auxiliary filter coefficients wₐᵤₓ(i+1) to main NLMS equalizer 204. The number of sets of coefficients wₐᵤₓ(i+1) copied and the periods during the first pass in which the sets are copied may vary from one implementation to the next.

Delay buffer 214 delays received signal y(i) to generate delayed signal y_{delayed}(i). Delayed signal y_{delayed}(i) is then provided to main NLMS equalizer 204 which performs a pass (i.e., the second stage) over the delayed samples of received signal y(i). Similar to NLMS equalizer 104 of prior-art receiver 100, main NLMS equalizer 204 is an update loop, comprising finite-impulse response (FIR) filter 208, coefficient updater 210, and error calculator 212. Coefficient updater 210 generates sets of main filter coefficients wₘₐᵢₙ(i+1) in a manner analogous to that of coefficient updater 110 of prior-art receiver 100 (e.g., as shown in Equation (4)). Note however that, when a set of auxiliary filter coefficients wₐᵤₓ(i+1) is received from auxiliary NLMS equalizer 216, coefficient updater 210 uses the received set of auxiliary filter coefficients Wₐᵤₓ(i+1) as a set of main filter coefficients wₘₐᵢₙ(i+1). FIR filter 208 applies the sets of main filter coefficients wₘₐᵢₙ(i+1) to delayed signal y_{delayed}(i), and outputs equalized signal \hat{x}ₘₐᵢₙ(i). Error calculator 212 calculates the error of equalized signal \hat{x}ₘₐᵢₙ(i) and provides error signal eₘₐᵢₙ*(i) to coefficient updater 210. Equalized signal \hat{x}ₘₐᵢₙ(i) is then output to downstream processing 206 which performs operations analogous to those of downstream processing 106 of prior-art receiver 100.

As an example of the operation of receiver 200, assume that auxiliary NLMS equalizer 216 is adapted to copy the third set of updated auxiliary filter coefficients wₐᵤₓ(3). At first, auxiliary NLMS equalizer equalizes received signal y(i) using an initial set of auxiliary coefficients wₐᵤₓ(0). During the next three iterations, auxiliary NLMS equalizer generates the first, second, and third updated sets of auxiliary filter coefficients wₐᵤₓ(1), wₐᵤₓ(2), and wₐᵤₓ(3), respectively. After the third set of auxiliary filter coefficients wₐᵤₓ(3) is generated, auxiliary NLMS equalizer 216 is triggered to copy the third set to main NLMS equalizer 204. Auxiliary NLMS equalizer 216 then runs until all samples of received signal y(i) have been equalized. Optionally, auxiliary NLMS equalizer 216 may be shut down to conserve power.

Delay buffer 214 delays received signal y(i) for a predetermined period of time. To accomplish this delay, delay buffer 214 can be modeled as a first-in, first-out queue. Suppose for this example that the third set of auxiliary filter coefficients wₐᵤₓ(3) are to be used by main NLMS equalizer 204 as the initial set of main filter coefficients wₘₐᵢₙ(0) (i.e., wₘₐᵢₙ(0)=wₐᵤₓ(3)). Delay buffer 214 will therefore delay received signal y(i) so that main NLMS equalizer 204 begins equalizing delayed signal y_{delayed}(i) as soon as the third set of auxiliary filter coefficients wₐᵤₓ(3) are copied. Once this occurs, FIR filter applies the initial set of main filter coefficients wₘₐᵢₙ(0) to delayed signal y_{delayed}(i), and outputs equalized signal \hat{x}ₘₐᵢₙ(i). Error calculator 212 calculates error signal eₘₐᵢₙ(i) based on equalized signal \hat{x}ₘₐᵢₙ(i) and provides error signal eₘₐᵢₙ(i) to coefficient updater 210. Coefficient updater 210 then calculates the next set of main filter coefficients wₘₐᵢₙ(1) based on (1) delayed received signal y_{delayed}(i), (2) the previous set of main filter coefficients (i.e., coefficients wₘₐᵢₙ(0)), and (3) error eₘₐᵢₙ(i) as shown in Equation (4). This process is repeated, updating the sets of main filter coefficients wₘₐᵢₙ(i+1) with each iteration, until all of the samples of delayed signal y_{delayed}(i) are equalized.

Copying Sets of Coefficients to the Main NLMS Equalizer

As described above, the number of sets of auxiliary filter coefficients wₐᵤₓ(i+1) supplied and the periods during the first pass in which the sets are supplied may vary from one implementation to the next. One particularly advantageous period for supplying a set of auxiliary filter coefficients wₐᵤₓ(i+1) occurs when the receiver is training to channel conditions (e.g., immediately following a discontinuity in transmission or during startup). As described in the “Background,” failure to rapidly converge on the minimum-mean-square error (MMSE) during this period may lead to errors in recovering the one or more output data streams, and consequently, the data may need to be retransmitted. By providing a set of auxiliary filter coefficients wₐᵤₓ(i+1) to main NLMS equalizer 204 at the beginning of a training period, main NLMS equalizer 204 is capable of converging on the MMSE quicker than NLMS equalizer 104 of prior-art receiver 100. As a result, receiver 200 is capable of achieving fewer errors and fewer retransmissions than prior-art receiver 100.

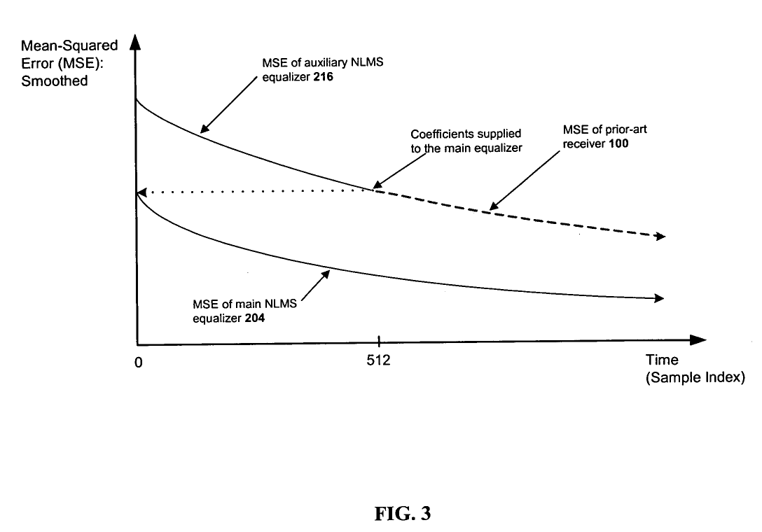

FIG. 3 graphically illustrates representations of mean-squared error (MSE) profiles for receiver 200 and prior-art receiver 100. As shown, the MSE of auxiliary NMLS equalizer 216 of receiver 200 follows the profile of the MSE of prior-art receiver 100 (shown in dashed line). After auxiliary NMLS equalizer 216 is triggered to copy the set of updated auxiliary coefficients wₐᵤₓ(i+1), main NLMS equalizer 204 begins equalizing delayed signal y_{delayed}(i), and the resulting MSE profile is lower than that of prior-art receiver 100.

The copying of sets of auxiliary filter coefficients wₐᵤₓ(i+1) may be triggered using any of a number of methods. In one such method, suggested in the example above, a set of auxiliary filter coefficients wₐᵤₓ(i+1) is provided after a predetermined number of iterations of auxiliary NLMS equalizer 216. In another such method, auxiliary NLMS equalizer 216 provides a set of auxiliary filter coefficients wₐᵤₓ(i+1) after a certain condition is met. For example, a set of auxiliary filter coefficients wₐᵤₓ(i+1) may be provided after auxiliary NLMS equalizer 216 achieves a predetermined MSE threshold. In this case, the time at which the set of auxiliary filter coefficients wₐᵤₓ(i+1) is copied may vary from transmission to transmission. Accordingly, delay buffer 214 would be designed to accommodate the varying startup times of main NLMS equalizer 204.

It will be further understood that various changes in the details, materials, and arrangements of the parts which have been described and illustrated in order to explain the nature of this invention may be made by those skilled in the art without departing from the scope of the invention as expressed in the following claims. For example, although the present invention is described in terms of equalizing a digital signal, the present invention is not so limited. The present invention may also be used to equalize an analog signal.

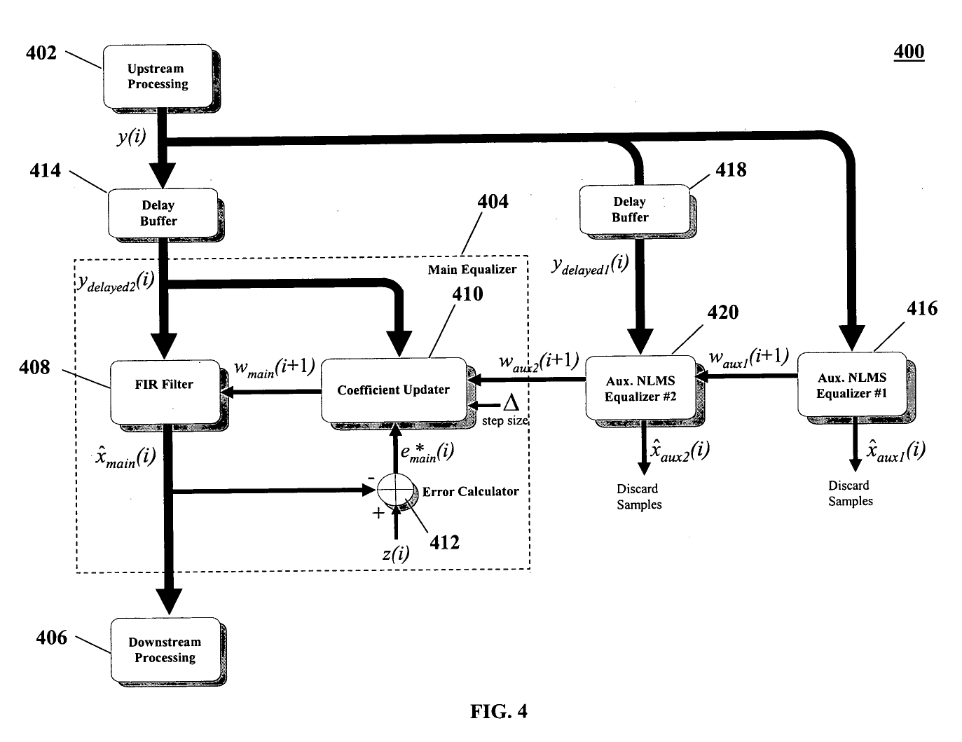

While the embodiment of FIG. 2 has been described in regards to two stages of equalization, the present invention is not so limited. According to various embodiments of the present invention, a receiver may have more than two stages of equalization. Except for the first stage of equalization, each stage of equalization may be connected to a previous stage of equalization in a pipelined manner such that each stage equalizes a delayed version of the received signal using one or more sets of coefficients copied from the previous equalization stage. One such embodiment is suggested in FIG. 4.

FIG. 4 shows a simplified block diagram of a receiver 400 having multiple pipelined stages of equalization with coefficient copying according to one embodiment of the present invention. Receiver 400 has upstream processing 402 and downstream processing 406 which perform operations analogous to those of the equivalent processing of receiver 200. Auxiliary NLMS equalizer #1 416 equalizes received signal y(i) in a manner similar to that of auxiliary NLMS equalizer 216 of receiver 200 and copies a set of auxiliary filter coefficients wₐᵤₓ₁(i) to auxiliary NLMS equalizer #2 420. Delay buffer 418 delays received signal y(i) for a period of time until the set of auxiliary filter coefficients wₐᵤₓ₁(i) are copied and provides a first delayed signal y_{delayed1}(i) to auxiliary NLMS equalizer #2 420. Auxiliary NLMS equalizer #2 420 equalizes first delayed signal y_{delayed1}(i) in a manner similar to that of main NLMS equalizer 204 of receiver 200 (e.g., using the set of copied coefficients wₐᵤₓ₁(i)). In so doing, auxiliary NLMS equalizer #2 420 generates sets of auxiliary filter coefficients wₐᵤₓ₂(i) and copies a set of auxiliary filter coefficients wₐᵤₓ₂(i) to main NLMS equalizer 404. Delay buffer 414 delays received signal y(i) for a period of time until the set of auxiliary filter coefficients wₐᵤₓ₂(i) is copied and provides a second delayed signal y_{delayed2}(i) to main NLMS equalizer 404. Main NLMS equalizer 404 then equalizes second delayed signal y_{delayed2}(i) in a manner similar to that of main NLMS equalizer 204 of receiver 200 (e.g., using the set of copied auxiliary filter coefficients wₐᵤₓ₂(i)) and outputs equalized signal \hat{x}ₘₐᵢₙ(i).

As demonstrated in the embodiment of FIG. 4, additional equalization stages can increase the latency of the main equalizer. The additional latency can be reduced by using faster processing in the additional equalization stages. In designing a receiver with more than two equalization stages, the number of equalization stages should be selected such that latency created by the more than two equalization stages does not offset the benefits achieved in reducing the number of retransmissions that would otherwise occur without the additional stages of equalization.

While the present invention is described in terms of multiple stages of equalization implemented in separate processing, the present invention is not so limited. Two or more stages of equalization may be implemented iteratively using a single block of processing.

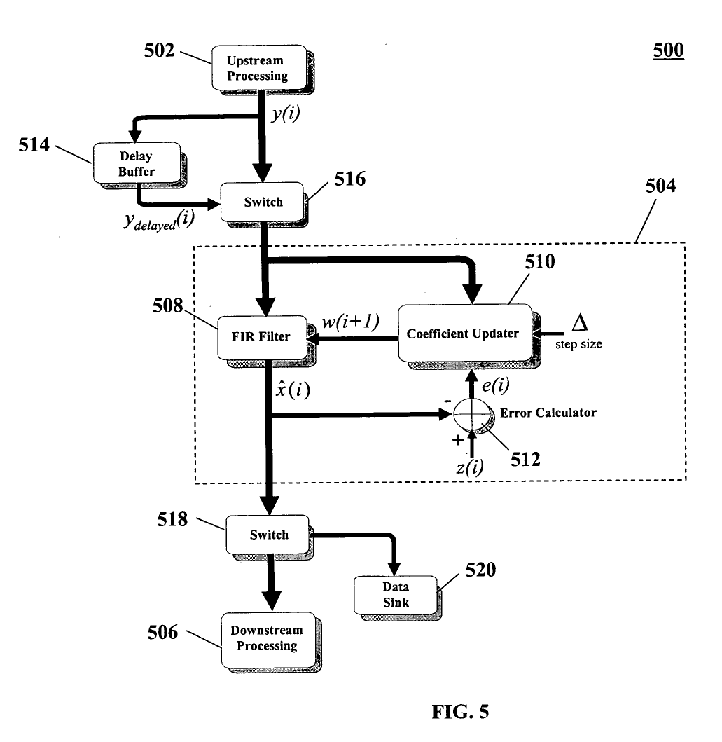

FIG. 5 shows a simplified block diagram of a receiver 500 according to one embodiment of the present invention that has two stages of equalization which are implemented iteratively. Receiver 500 has upstream processing 502 which performs operations analogous to that of upstream processing 102 of prior-art receiver 100 to generate received signal y(i). NLMS equalizer 504 performs a first pass (i.e., the first stage) over received signal y(i) by equalizing received signal y(i) in a manner similar to that of NLMS equalizer 104 of prior-art receiver 100. After NLMS equalizer 504 has received the samples of received signal y(i), switch 516 is activated and delay buffer 514 provides a delayed version y_{delayed}(i) of received signal y(i). NLMS equalizer 504 equalizes delayed signal y_{delayed}(i) (i.e., the second stage) in a manner similar to that of main NLMS equalizer 204 of receiver 200. Note that in doing so, the last set of coefficients w(i+1) generated during the first stage are used as the first set of coefficients w(i+1) for the second stage. Equalized signal \hat{x}(i) is output to switch 518. During the first stage of equalization, equalized signal \hat{x}(i) is output to data sink 520. During the second stage of equalization, equalized signal \hat{x}(i) is output to downstream processing 506, which performs operations analogous to those of downstream processing 106 of prior-art receiver 100.

In the embodiment of FIG. 5, equalizing all of the samples of received signal y(i) during the first pass can significantly increase the latency of receiver 500. To minimize this latency, switch 516 may be activated after only a portion of received signal y(i) has been equalized. In designing a receiver that implements two stages of equalization iteratively, the number of samples in the first pass should be determined by balancing the latency gained by equalizing those samples and the benefits of the additional initial convergence. Furthermore, in designing a receiver that implements two or more stages of equalization iteratively, the number of stages selected should be determined by balancing the latency gained by adding iterations and the benefits of the additional initial convergence.

Various embodiments of the present invention may envisioned which implement both pipelined equalizers and iterative stages of equalization. In such embodiments a receiver may comprise two or more pipelined equalizers of which one or more of the equalizers implements two or more iterative stages of equalization.

Additional embodiments of the present invention may be implemented in apparatuses that have two or more receivers, such as apparatuses that receive transmit-diverse signals. The two or more receivers may be adapted so that one or more receivers act as auxiliary receivers by generating sets of auxiliary coefficients and the other one or more receivers act as main receivers by using the sets of auxiliary coefficients for equalizing received signals. For example, apparatuses designed to meet 3^{rd} generation partnership project (3GPP) standards having a receiver that meets the R99 standards, such as a RAKE receiver, and an advanced receiver for receiving Release 6 or Release 7 signals could be used for this invention.

Further embodiments of the present invention may be envisioned in which equalizers other than chip-rate NLMS equalizers are used in place of the main equalizer, the auxiliary equalizer, or both the main and the auxiliary equalizers. Such other equalizers include but are not limited to LMS equalizers, recursive least-squares equalizers, and any other equalizers commonly known in the art that adaptively generates coefficients. Furthermore, the present invention is not limited to the use of FIR filters. Other filters may be used without departing from the scope of this invention, including but not limited to infinite impulse response (IIR) filters.

Yet further embodiments of the present invention may be envisioned which employ coefficient copying and other commonly known methods to reduce the occurrences of retransmissions. For example, the present invention may also be combined with gear shifting approaches as described in the “Background.” According to some embodiments, one or more auxiliary equalizers may utilize larger step sizes \tilde{Δ} for more rapid initial convergence on the MMSE. Then, the main equalizer and possibly one or more auxiliary equalizers may use smaller step sizes \tilde{Δ} for more accurate convergence on the MMSE. Using this approach, the step sizes \tilde{Δ} may be selected to decrease in size, such that the first auxiliary equalizer uses the largest step size \tilde{Δ} and the main equalizer utilizes the smallest step size \tilde{Δ}.

Yet still further embodiments of the present invention may be envisioned in which coefficient copying is combined with the use of additional training references as taught in PCT patent application no. PCT/US07/00622. For example, for applications adhering to 3^{rd} generation partnership project (3GPP) standards, the synchronization (SCH) channel, which is transmitted during the first 10 percent of each slot, has a bit pattern known by the receiver. This channel may be used in addition to the pilot channel so that the known reference x(i) in Equation (5) comprises pilot z(i) and the known data of the SCH channel. The increased power from the additional training reference enables the receiver to calculate more accurate errors and as a result, convergence on the MMSE can be accelerated.

The present invention may be implemented as circuit-based processes, including possible implementation as a single integrated circuit (such as an ASIC or an FPGA), a multi-chip module, a single card, or a multi-card circuit pack. As would be apparent to one skilled in the art, various functions of circuit elements may also be implemented as processing blocks in a software program. Such software may be employed in, for example, a digital signal processor, micro-controller, or general-purpose computer.

The present invention can be embodied in the form of methods and apparatuses for practicing those methods. The present invention can also be embodied in the form of program code embodied in tangible media, such as magnetic recording media, optical recording media, solid state memory, floppy diskettes, CD-ROMs, hard drives, or any other machine-readable storage medium, wherein, when the program code is loaded into and executed by a machine, such as a computer, the machine becomes an apparatus for practicing the invention. The present invention can also be embodied in the form of program code, for example, whether stored in a storage medium, loaded into and/or executed by a machine, or transmitted over some transmission medium or carrier, such as over electrical wiring or cabling, through fiber optics, or via electromagnetic radiation, wherein, when the program code is loaded into and executed by a machine, such as a computer, the machine becomes an apparatus for practicing the invention. When implemented on a general-purpose processor, the program code segments combine with the processor to provide a unique device that operates analogously to specific logic circuits. The present invention can also be embodied in the form of a bitstream or other sequence of signal values electrically or optically transmitted through a medium, stored magnetic-field variations in a magnetic recording medium, etc., generated using a method and/or an apparatus of the present invention.

The use of figure numbers and/or figure reference labels in the claims is intended to identify one or more possible embodiments of the claimed subject matter in order to facilitate the interpretation of the claims. Such use is not to be construed as necessarily limiting the scope of those claims to the embodiments shown in the corresponding figures.

It should be understood that the steps of the exemplary methods set forth herein are not necessarily required to be performed in the order described, and the order of the steps of such methods should be understood to be merely exemplary. Likewise, additional steps may be included in such methods, and certain steps may be omitted or combined, in methods consistent with various embodiments of the present invention.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

We claim:

1. A method for equalizing a received signal, the method comprising:
(a) performing a first stage of equalization to generate a set of auxiliary filter coefficients based on the received signal; and
(b) performing a second stage of equalization to generate a set of main filter coefficients based on a delayed version of the received signal and the set of auxiliary filter coefficients.

2. The invention of claim 1, wherein step (a) further comprises performing one or more additional stages of equalization, prior to the first stage of equalization, and each additional stage of equalization generates a set of filter coefficients for a subsequent stage of equalization.

3. The invention of claim 1, wherein:
step (a) comprises:
(a1) filtering the received signal based on an initial set of filter coefficients to obtain an auxiliary equalized signal;
(a2) calculating an auxiliary error signal based on the auxiliary equalized signal; and
(a3) adaptively generating the set of auxiliary filter coefficients based on the auxiliary error signal; and
step (b) comprises:
(b1) filtering the delayed version of the received signal based on the set of auxiliary filter coefficients to obtain a main equalized signal;
(b2) calculating a main error signal based on the main equalized signal; and
(b3) adaptively generating the set of main filter coefficients based on the main error signal.

4. The invention of claim 1, wherein only one set of auxiliary filter coefficients is applied to the delayed version of the received signal.

5. The invention of claim 1, wherein the first stage of equalization is terminated after generating the set of auxiliary filter coefficients.

6. The invention of claim 1, wherein the sets of auxiliary filter coefficients is provided to the second stage of equalization after a predetermined number of iterations of the first stage of equalization.

7. The invention of claim 1, wherein the set of auxiliary filter coefficients is provided to the second stage of equalization after a predetermined error threshold has been achieved by the first stage of equalization.

8. An apparatus for equalizing a received signal, the apparatus comprising one or more equalizers adapted to:
(a) perform a first stage of equalization to generate a set of auxiliary filter coefficients based on the received signal; and
(b) perform a second stage of equalization to generate a set of main filter coefficients based on a delayed version of the received signal and the set of auxiliary filter coefficients.

9. The invention of claim 8, wherein each equalizer comprises:
(a1) a filter adapted to filter a version of the received signal to obtain an equalized signal;
(a2) an error calculator adapted to calculate an error signal based on the equalized signal; and
(a3) a coefficient updater adapted to adaptively generate a corresponding set of filter coefficients based on the error signal.

10. The invention of claim 8, wherein the one or more equalizers comprise an auxiliary equalizer and a main equalizer, wherein:
the auxiliary equalizer is adapted to perform the first stage of equalization and provide the set of auxiliary filter coefficients to the main equalizer; and
the main equalizer is adapted to perform the second stage of equalization.

11. The invention of claim 10, further comprising one or more additional equalizers connected in a pipelined manner, prior to the first equalizer, wherein each additional equalizer is adapted to generate a set of filter coefficients for a subsequent equalizer.

12. The invention of claim 11, wherein one or more of the equalizers is adapted to iteratively perform two or more stages of equalization.

13. The invention of claim 8, comprising one equalizer adapted to iteratively perform the first stage of equalization and the second stage of equalization.

14. The invention of claim 13, wherein the one equalizer is adapted to perform one or more additional stages of equalization, prior to the first stage of equalization, wherein each additional stage of equalization generates a set of filter coefficients for a subsequent stage of equalization.

15. The invention of claim 8, wherein the one or more equalizers are adapted to apply only one set of auxiliary filter coefficients to the delayed version of the received signal.

16. The invention of claim 8, wherein the one or more equalizers are adapted to terminate the first stage of equalization after generating the set of auxiliary filter coefficients.

17. The invention of claim 8, wherein the one or more equalizers are adapted to provide the set of auxiliary filter coefficients to the second stage of equalization after a predetermined number of iterations of the second stage of equalization.

18. The invention of claim 8, wherein the one or more equalizers are adapted to provide the set of auxiliary filter coefficients to the second stage of equalization after a predetermined threshold has been achieved by the first stage of equalization.

19. An apparatus for equalizing a received signal, the apparatus comprising:
(a) a means for performing a first stage of equalization to generate a set of auxiliary filter coefficients based on the received signal; and
(b) a means for performing a second stage of equalization to generate a set of main filter coefficients based on a delayed version of the received signal and the set of auxiliary filter coefficients.
